(19) United States
(12) Patent Application Publication
(10) Pub. No.: US 2014/0214364 A1
(43) Pub. Date: Jul. 31, 2014

(54) METHOD OF ESTIMATING OFFSET OF MAGNETIC SENSOR

(71) Applicant: Yamaha Corporation, Hamamatsu-Shi (JP)

(72) Inventor: Ibuki Handa, Hamamatsu-shi (JP)

(73) Assignee: Yamaha Corporation, Hamamatsu-Shi (JP)

(21) Appl. No.: 14/166,014

(22) Filed: Jan. 28, 2014

(30) Foreign Application Priority Data
Jan. 31, 2013 (JP) 2013-017747

(51) Int. Cl. G01R 33/00

(52) U.S. Cl. CPC G01R 33/0023
USPC 702/182

(57) ABSTRACT

An offset estimation method calculates attitude data representing an attitude variation of equipment from a reference attitude thereof based on angular velocity data that is outputted from an angular velocity sensor and that represents angular velocity of the equipment. The offset estimation method further calculates an estimation value of the offset minimizing an error between first variable vectors associated to the attitude data and second variable vectors associated to magnetic data that are successively outputted from a magnetic sensor. The first variable vector is obtained by changing a reference variable vector in accordance with the attitude variation represented by the attitude data, the reference variable vector representing geomagnetism when the equipment is placed in the reference attitude, and the second variable vector is obtained by subtracting the estimation value of the offset from the magnetic data.

### BACKGROUND OF THE INVENTION

1. Technical Field of the Invention

The present invention relates to a method of and apparatus for estimating an offset of a magnetic sensor.

2. Description of the Related Art

In recent years, a three-dimensional magnetic sensor is provided in a portable equipment, such as a portable phone, or a movable object, such as a car, for detecting geomagnetism. Generally, the three-dimensional magnetic sensor includes three magnetic sensor modules for dividing a vector of a magnetic field into components in three directions and detecting respective scalar quantities. The three-dimensional magnetic sensor outputs magnetic data, which are three-dimensional vector data having the scalar quantities output from the three magnetic sensor modules as three components.

Meanwhile, equipment, such as a portable telephone, equipped with the three-dimensional magnetic sensor often includes electric and magnetic parts, such as various kinds of metals that can be magnetized and electric circuits, generating a magnetic field. In this case, magnetic data output by the three-dimensional magnetic sensor also include a vector representing an internal magnetic field generated by the parts provided in the equipment in addition to a vector representing geomagnetism.

In order to correctly detect a value of the geomagnetism, therefore, it is necessary to perform a correction process of removing a vector representing a disturbance component, such as the internal magnetic field generated by the parts of the equipment, from the magnetic data output by the three-dimensional magnetic sensor. The disturbance component should be removed from the magnetic data output by the three-dimensional magnetic sensor through the correction process in order to obtain a correct value of the geomagnetism. Such a disturbance component is referred to as an offset of the three-dimensional magnetic sensor.

The internal magnetic field, which is generated by the parts of the equipment, is a magnetic field having a uniform direction and a uniform magnitude with respect to the equipment. In a case in which the internal magnetic field is found from the three-dimensional magnetic sensor provided in the equipment, therefore, the internal magnetic field is represented as a vector having a uniform direction and a uniform magnitude even when the equipment is placed in any attitude.

On the other hand, the geomagnetism is a magnetic field having a horizontal component directed to a north magnetic pole and a perpendicular component decided by a magnetic dip. The geomagnetism is a uniform magnetic field having a uniform direction and a uniform magnitude with respect to the ground. In a case in which the attitude of the equipment is changed with respect to the ground, therefore, the direction of the geomagnetism viewed from the equipment is also changed. That is, when viewed from the three-dimensional magnetic sensor provided in the equipment, the geomagnetism is represented as a vector having a direction changed as the attitude of the equipment is changed and a uniform magnitude.

Patent literature 1 discloses a method of separating between geomagnetism and internal magnetic field. By using properties of geomagnetism and internal magnetic field, the disclosed method divides a plurality of magnetic data acquired while changing the attitude of equipment, i.e. the attitude of a three-dimensional magnetic sensor into a component representing the internal magnetic field having a uniform direction and magnitude when viewed from the magnetic sensor and a component representing the geomagnetism having a direction changed as the attitude of the three-dimensional magnetic sensor is changed and a uniform magnitude, and calculates the divided component representing the internal magnetic field as an offset.
[Patent Literature 1] Japanese Patent Application Publication No. 2012-198112

In a case in which the offset of the three-dimensional magnetic sensor is calculated using the conventional method, however, it is necessary to acquire a plurality of magnetic data while sufficiently changing the attitude of the three-dimensional magnetic sensor. In a case in which the attitude of the three-dimensional magnetic sensor is not sufficiently changed, therefore, it is not possible to accurately calculate the offset.

### SUMMARY OF THE INVENTION

The present invention has been made in view of the above problem, and it is an object of the present invention to provide an offset estimation method and apparatus that is capable of estimating an offset even when the change in attitude of a three-dimensional magnetic sensor is smaller than the change in attitude of the three-dimensional magnetic sensor necessary in a case in which the offset is calculated using the conventional method.

In order to solve the above problems, the present invention provides a method of estimating an offset of a magnetic sensor that is provided in equipment for detecting magnetism including geomagnetism, the equipment having an angular velocity sensor for detecting an angular velocity of the equipment. The inventive method comprises: calculating attitude data representing an attitude variation of the equipment from a reference attitude thereof based on angular velocity data that is outputted from the angular velocity sensor and that represents the detected angular velocity of the equipment; and calculating an estimation value of the offset minimizing an error between a predetermined number of first variable vectors associated to a predetermined number of the attitude data that are successively calculated in response to the angular velocity data outputted from the angular velocity sensor and a predetermined number of second variable vectors associated to a predetermined number of the magnetic data that are successively outputted from the magnetic sensor and that represent the detected magnetism including the geomagnetism. The first variable vector is obtained by changing a reference variable vector in accordance with the attitude variation represented by the attitude data, the reference variable vector representing the geomagnetism when the equipment is placed in the reference attitude, and the second variable vector is obtained by subtracting the estimation value of the offset from the magnetic data.

The offset estimation method according to the present invention calculates the estimation value of the offset based on the magnetic data and the angular velocity data. The angular velocity data are data representing the change in attitude of the equipment. In the angular velocity data, the change in attitude of the equipment is correctly represented.

In a case in which the attitude of the equipment is changed, the attitude change is expressed as distribution of a plurality of points indicated by a plurality of magnetic data output from the three-dimensional magnetic sensor in the three-axis rectangular coordinate system for expressing the detection result of the three-dimensional magnetic sensor. And the estimation value of the offset of the three-dimensional magnetic sensor is calculated using a statistical method based on the distribution shape of the points. That is, the estimation value of the offset of the three-dimensional magnetic sensor is calculated based on the distribution shape of a plurality of points set based on the change in attitude of the equipment. If it is possible to correctly detect the change in attitude of the equipment and to correctly reflect the detection result with respect to calculation to calculate the estimation value of the offset, therefore, it is possible to accurately calculate the estimation value of the offset.

The offset estimation method according to the present invention calculates the estimation value of the offset based on the angular velocity data in addition to the magnetic data. Consequently, it is possible for the offset estimation method according to the present invention to correctly reflect the change in attitude of the equipment with respect to calculation to calculate the estimation value of the offset as compared with a case in which the estimation value of the offset is calculated based only on the magnetic data. As a result, it is possible for the offset estimation method to accurately calculate the estimation value of the offset even in a case in which the change in attitude of the equipment is small.

Specifically, the estimation value of the offset is calculated as an offset variable vector that minimizes an objective function representing the error between the predetermined number of the first variable vectors and the predetermined number of the second variable vectors.

Preferably, the inventive method further comprises: determining whether or not a degree of difference between a distribution shape of a predetermined number of points indicated by the predetermined number of the first variable vectors and a distribution shape of a predetermined number of points indicated by the predetermined number of the second variable vectors is within a predetermined range; and adopting the estimation value of the offset as the offset of the magnetic sensor in case that the degree of the difference is determined to be within the predetermined range.

Preferably, the inventive method further comprises: determining whether or not a degree of difference between components of an estimated geomagnetic data distribution matrix representing distribution of the predetermined number of the first variable vectors and components of a magnetic data distribution matrix representing distribution of the predetermined number of the magnetic data is within a predetermined range; and adopting the estimation value of the offset as the offset of the magnetic sensor in case that the degree of the difference is determined to be within the predetermined range.

Preferably, the inventive method further comprises: generating an accuracy index representing accuracy of calculation for calculating the estimation value of the offset; and determining whether or not the accuracy index is equal to or greater than a predetermined threshold value, wherein the estimation value of the offset is calculated in case that the accuracy index is determined to be equal to or greater than the predetermined threshold value, and the estimation value of the offset is not calculated in case that the accuracy index is determined to be less than the predetermined threshold value.

Preferably, the error is represented by a function using variables including elements of the reference variable vector and elements of an offset variable vector representing the estimation value of the offset, and the accuracy index is a minimum eigenvalue of a coefficient matrix that is given by expressing the error in a quadratic form based on the variables.

Preferably, the predetermined threshold value is a positive real number.

In addition, the present invention further provides an apparatus for estimating an offset of a magnetic sensor that is provided in equipment for detecting magnetism including geomagnetism, the equipment having an angular velocity sensor for detecting an angular velocity of the equipment, the apparatus comprising one or more processors configured to: calculate attitude data representing an attitude variation of the equipment from a reference attitude thereof based on angular velocity data that is outputted from the angular velocity sensor and that represents the detected angular velocity of the equipment; and calculate an estimation value of the offset minimizing an error between a predetermined number of first variable vectors associated to a predetermined number of the attitude data that are successively calculated in response to the angular velocity data outputted from the angular velocity sensor and a predetermined number of second variable vectors associated to a predetermined number of the magnetic data that are successively outputted from the magnetic sensor and that represent the detected magnetism including the geomagnetism, wherein the first variable vector is obtained by changing a reference variable vector in accordance with the attitude variation represented by the attitude data, the reference variable vector representing the geomagnetism when the equipment is placed in the reference attitude, and the second variable vector is obtained by subtracting the estimation value of the offset from the magnetic data.

Specifically, the estimation value of the offset is calculated as an offset variable vector that minimizes an objective function representing the error between the predetermined number of the first variable vectors and the predetermined number of the second variable vectors.

Preferably, the one or more processors of the inventive apparatus are further configured to: determine whether or not a degree of difference between a distribution shape of a predetermined number of points indicated by the predetermined number of the first variable vectors and a distribution shape of a predetermined number of points indicated by the predetermined number of the second variable vectors is within a predetermined range; and adopt the estimation value of the offset as the offset of the magnetic sensor in case that the degree of the difference is determined to be within the predetermined range.

Preferably, the one or more processors of the inventive apparatus are further configured to: determine whether or not a degree of difference between components of an estimated geomagnetic data distribution matrix representing distribution of the predetermined number of the first variable vectors and components of a magnetic data distribution matrix representing distribution of the predetermined number of the magnetic data is within a predetermined range; and adopt the estimation value of the offset as the offset of the magnetic sensor in case that the degree of the difference is determined to be within the predetermined range.

Preferably, the one or more processors of the inventive apparatus are further configured to: generate an accuracy index representing accuracy of calculation for calculating the estimation value of the offset; and determine whether or not the accuracy index is equal to or greater than a predetermined threshold value, wherein the estimation value of the offset is calculated in case that the accuracy index is determined to be equal to or greater than the predetermined threshold value, and the estimation value of the offset is not calculated in case that the accuracy index is determined to be less than the predetermined threshold value.

Preferably, the error is represented by a function using variables including elements of the reference variable vector and elements of an offset variable vector representing the estimation value of the offset, and the accuracy index is a minimum eigenvalue of a coefficient matrix that is given by expressing the error in a quadratic form based on the variables. Preferably, the predetermined threshold value is a positive real number.

### BRIEF DESCRIPTION OF THE DRAWINGS

FIG. 1 is a block diagram showing a configuration of portable equipment according to an embodiment of the present invention.

FIG. 2 is a perspective view showing the external appearance of the portable equipment according to the embodiment of the present invention.

FIG. 3 is an explanatory diagram illustrating geomagnetism and an internal magnetic field.

FIG. 4 is another explanatory diagram illustrating the geomagnetism and the internal magnetic field.

FIG. 5 is a block diagram showing a function of an offset estimation apparatus according to a first embodiment of the present invention.

FIG. 6 is an explanatory diagram illustrating a noise magnetic field.

FIG. 7 is a block diagram showing a function of an offset estimation apparatus according to a second embodiment of the present invention.

### DETAILED DESCRIPTION OF THE INVENTION

### A. First Embodiment

A first embodiment of the present invention will be described with reference to the accompanying drawings.

### 1. CONFIGURATION OF EQUIPMENT AND CONFIGURATION OF SOFTWARE

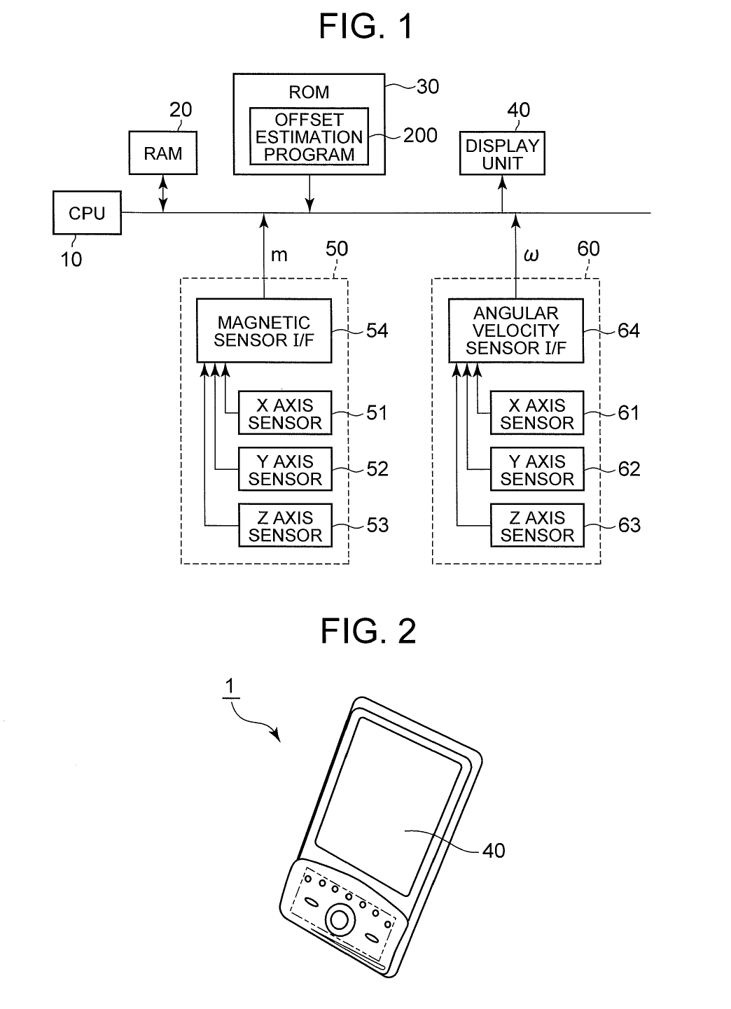

FIG. 1 is a block diagram showing a configuration of portable equipment according to an embodiment of the present invention and FIG. 2 is a perspective view showing the external appearance of the portable equipment. The portable equipment 1 (hereinafter, also simply referred to as equipment) estimates a direction of geomagnetism B_{g} when viewed from the portable equipment 1 based on output from a three-dimensional magnetic sensor and a three-dimensional angular velocity sensor included in the portable equipment 1.

The portable equipment 1 includes a CPU 10 connected to various kinds of configuration elements via buses for controlling the entirety of the apparatus, a RAM (accumulation unit) 20 functioning as a work area of the CPU 10, a ROM 30 for storing various kinds of programs, such as an offset estimation program 200 and data, a display unit 40 for displaying various kinds of information, and a communication unit (not shown) for performing communication.

In addition, the portable equipment 1 includes a three-dimensional magnetic sensor 50 for detecting a magnetic field, such as geomagnetism, on a unit time Δt basis, to output magnetic data M and a three-dimensional angular velocity sensor 60 for detecting angular velocity on a unit time Δt basis to periodically output angular velocity data W.

For example, the display unit 40 may display a direction of geomagnetism B_{g} estimated by the portable equipment 1 based on the magnetic data M and the angular velocity data W as an image such an arrow.

The three-dimensional magnetic sensor 50 includes an X axis magnetic sensor 51, a Y axis magnetic sensor 52, and a Z axis magnetic sensor 53. Each of the sensors may be configured using a magnetic impedance device (MI device), a magnetic resistance effect device (MR device), etc. A magnetic sensor I/F 54 converts analog output signals from the X axis magnetic sensor 51, the Y axis magnetic sensor 52, and the Z axis magnetic sensor 53 into digital signals to output magnetic data M. The magnetic data M are data representing a magnetic vector m, which is a three-dimensional vector represented by an x axis component, a y axis component, and a z axis component. More specifically, in a three-axis rectangular coordinate system fixed to the three-dimensional magnetic sensor 50 (hereinafter, referred to as a sensor coordinate system Σ_{S}), the magnetic vector m is a three-dimensional vector representing an output value from the X axis magnetic sensor 51 as an x axis component, an output value from the Y axis magnetic sensor 52 as a y axis component, and an output value from the Z axis magnetic sensor 53 as a z axis component.

Meanwhile, hereinafter, magnetic data M output based on a magnetic field detected by the three-dimensional magnetic sensor 50 at a time T=k will be expressed as magnetic data Mₖ obtained by attaching a subscript k to the magnetic data M and a three-dimensional vector represented by the magnetic data Mₖ will be expressed as a magnetic vector mₖ.

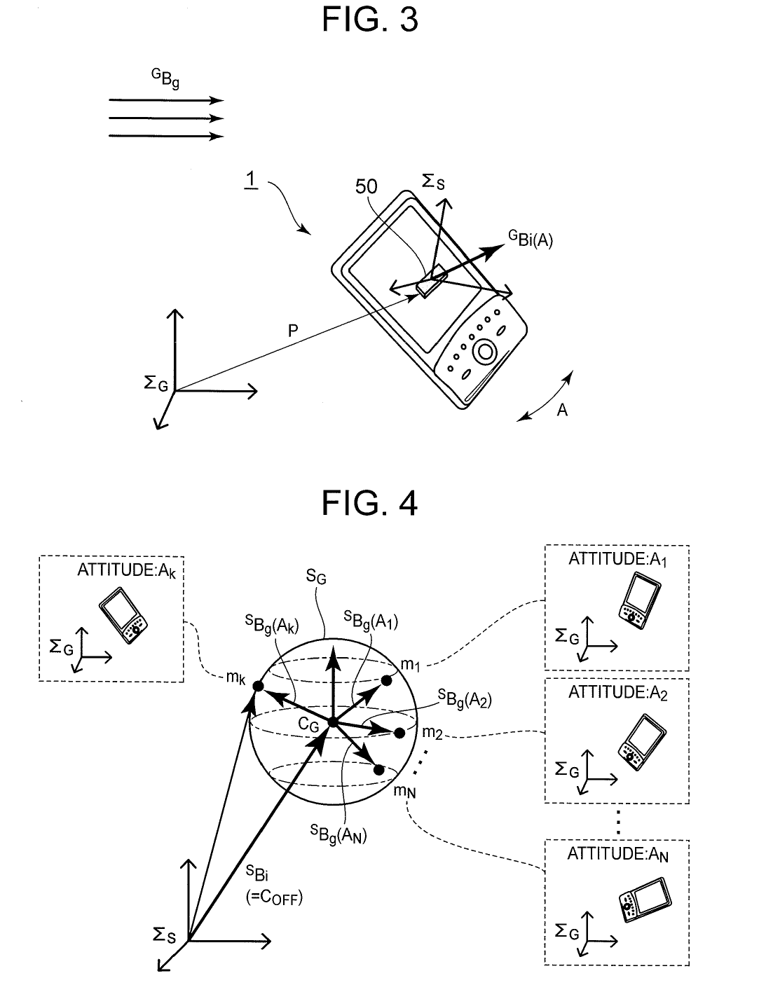

A magnetic field detected by the three-dimensional magnetic sensor 50 includes geomagnetism B_{g} and an internal magnetic field Bᵢ. Hereinafter, properties of the geomagnetism B_{g} and the internal magnetic field Bᵢ will be described with reference to FIGS. 3 and 4.

FIG. 3 is an explanatory diagram showing the geomagnetism B_{g} and the internal magnetic field Bᵢ in a three-axis rectangular coordinate system fixed to the ground (hereinafter, referred to as a ground coordinate system Σ_{G}). Meanwhile, an attitude A shown in FIG. 3 represents a direction of each axis of the sensor coordinate system Σ_{S} in the ground coordinate system Σ_{G} (that is, an attitude of the three-dimensional magnetic sensor 50 in the ground coordinate system Σ_{G}). In addition, a position P shown in FIG. 3 represents a position of the origin of the sensor coordinate system Σ_{S} in the ground coordinate system Σ_{G} (that is, a position of the three-dimensional magnetic sensor 50 in the ground coordinate system Σ_{G}).

Generally, the geomagnetism B_{g} is a magnetic field having a horizontal component directed to a north magnetic pole and a perpendicular component decided by a magnetic dip. The geomagnetism B_{g} is represented as a vector ^{G}B_{g} having a uniform direction and magnitude in the ground coordinate system Σ_{G} (Meanwhile, hereinafter, a superscript G attached to the left upper part of a symbol of a vector means that the vector is represented in the ground coordinate system Σ_{G}). That is, the direction and magnitude of the vector ^{G}B_{g} representing the geomagnetism B_{g} are not changed even when the attitude A and the position P of the portable equipment 1 are changed.

The internal magnetic field Bᵢ is a magnetic field having a uniform direction and a uniform magnitude when viewed from the portable equipment 1. For example, the internal magnetic field Bᵢ is a magnetic field generated by a physical component contained in the portable equipment 1. For this reason, a vector representing the internal magnetic field Bᵢ in ground coordinate system Σ_{G} is a vector, the direction of which is changed according to change in the attitude A of the portable equipment 1, and may be expressed as a vector ^{G}Bᵢ(A), which is a function of the attitude A.

FIG. 4 is a view showing a plurality of points on the sensor coordinate system Σ_{S} indicating N (predetermined number) magnetic vectors m₁ to m_{N} represented by N magnetic data M₁ to M_{N} output by the three-dimensional magnetic sensor 50 in a case in which a magnetic field is measured while the attitude A of the portable equipment 1 is changed from A₁ to A_{N}.

In the sensor coordinate system Σ_{S}, the internal magnetic field Bᵢ is represented as a vector ^{S}Bᵢ having a uniform direction and magnitude even when the attitude A and the position P of the portable equipment 1 are changed (That is, a superscript S attached to the left upper part of a symbol of a vector means that the vector is represented in sensor coordinate system Σ_{S}).

In the sensor coordinate system Σ_{S}, the geomagnetism B_{g} is represented as a vector ^{S}B_{g}(A) having a direction varying according to the attitude A of the portable equipment 1 and a uniform magnitude. The vector ^{S}B_{g}(A) represents a direction of the geomagnetism B_{g} when viewed from the sensor coordinate system Σ_{S}, i.e. a direction of the geomagnetism B_{g} when viewed from the portable equipment 1.

In a case in which the three-dimensional magnetic sensor 50 detects only the geomagnetism B_{g} and the internal magnetic field Bᵢ, the magnetic vector m represents the sum of the geomagnetism B_{g} and the internal magnetic field Bᵢ. That is, in this case, the magnetic vector m in the sensor coordinate system Σ_{S} represents the sum of the vector ^{S}Bᵢ and the vector ^{S}B_{g}(A).

In a case in which the vector ^{S}Bᵢ is positioned such that the start point (the initial point) of the vector ^{S}Bᵢ coincides with the origin of the sensor coordinate system Σ_{S}, the end point of the vector ^{S}Bᵢ is given as a point C_{G}. In addition, a spherical surface having the point C_{G} as a center and the magnitude of the geomagnetism B_{g} as a radius is given as a spherical surface S_{g}.

At this time, when a magnetic field is measured while the attitude A of the portable equipment 1 is changed from A₁ to A_{N}, a plurality of magnetic vectors m₁ to m_{N} represented by a plurality of magnetic data M₁ to M_{N} output from the three-dimensional magnetic sensor 50 indicates coordinates on the spherical surface S_{g} as shown in FIG. 4. Consequently, it is possible to calculate a direction and magnitude of a vector ^{S}B_{g}(Aₖ), i.e. the geomagnetism B_{g}, by subtracting coordinates of the point C_{G} from coordinates indicated by a magnetic vector mₖ (k=1, 2, . . . N).

A process of subtracting the coordinates indicated by the center point C_{G} of the spherical surface S_{g} from the coordinates indicated by the magnetic vector mₖ to acquire a correct direction of the geomagnetism B_{g}, which is a target to be detected, as described above is referred to as a correction process. In addition, a vector to be removed from the magnetic vector mₖ through the correction process is referred to as an offset c_{OFF} of the three-dimensional magnetic sensor 50. In an example shown in FIG. 4, the offset c_{OFF} is a vector ^{S}Bᵢ representing the internal magnetic field Bᵢ. In other words, the offset c_{OFF} is a vector representing the coordinates of the center point C_{G} of the spherical surface S_{g} in the sensor coordinate system Σ_{S}. Namely in this invention, the offset of the three-dimensional magnetic sensor is, for example, a difference between the vector representing the geomagnetism in the rectangular coordinate system and the output value from the three-dimensional magnetic sensor.

Meanwhile, since the magnetic data M output by the three-dimensional magnetic sensor 50 has a measurement error in a practical sense, the points represented by the magnetic vectors m₁ to m_{N} are stochastically distributed in the vicinity of the spherical surface S_{g} in a narrow sense.

Referring back to FIG. 1, the three-dimensional angular velocity sensor 60 shown in FIG. 1 includes an X axis angular velocity sensor 61, a Y axis angular velocity sensor 62, and a Z axis angular velocity sensor 63. An angular velocity sensor I/F 64 converts analog output signals from the respective sensors into digital signals to output angular velocity data W. The angular velocity data W are data representing an angular velocity vector o, which is a three-dimensional vector indicating angular velocities around the respective axes extending in three directions, in a three-axis rectangular coordinate system fixed to the portable equipment 1.

Meanwhile, hereinafter, angular velocity data W output based on an angular velocity detected by the three-dimensional angular velocity sensor 60 at a certain time T=k will be expressed as angular velocity data Wₖ obtained by attaching a subscript k to the angular velocity data W and a three-dimensional vector represented by the angular velocity data Wₖ will be expressed as an angular velocity vector ωₖ.

The CPU 10 executes the offset estimation program 200 stored in the ROM 30 to estimate the offset c_{OFF} of the three-dimensional magnetic sensor 50. That is, since the CPU 10 executes the offset estimation program 200, the CPU 10 functions as an offset estimation apparatus 100.

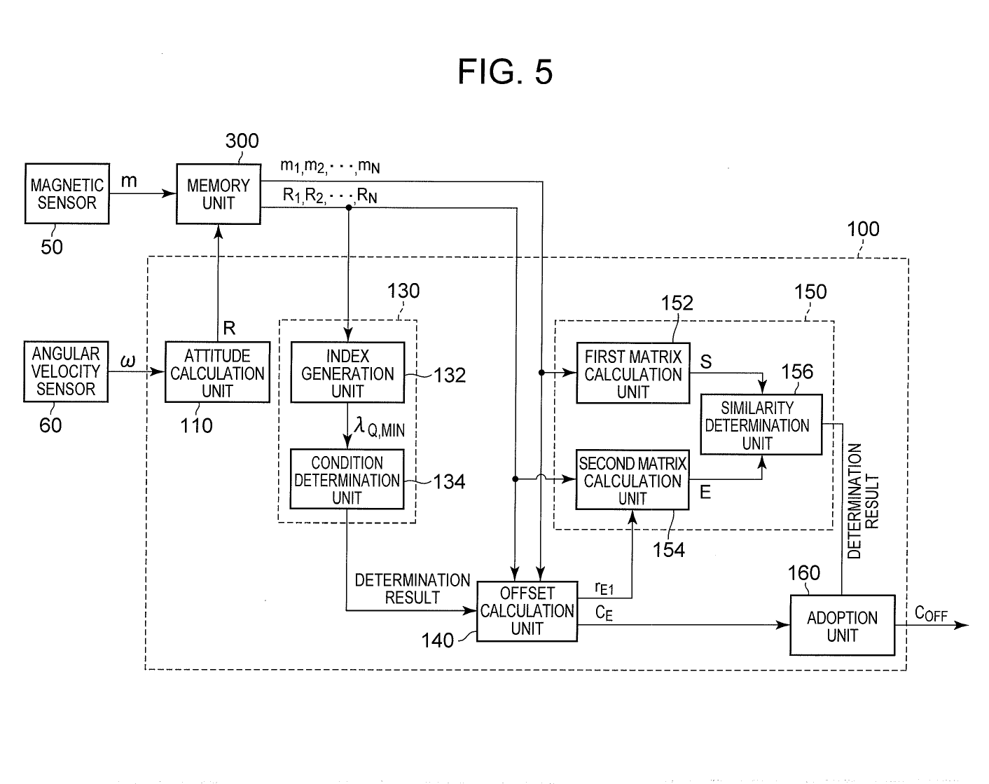

FIG. 5 is a function block diagram showing a function of the offset estimation apparatus 100.

The offset estimation apparatus 100 includes an attitude calculation unit 110, an accuracy determination unit 130, an offset calculation unit 140, a distribution shape determination unit 150, and an adoption unit 160.

The offset estimation apparatus 100 generates an estimation value c_{E} of the offset c_{OFF} of the three-dimensional magnetic sensor 50 based on the magnetic data M and the angular velocity data W. More specifically, the offset estimation apparatus 100 generates an estimation value C_{E} of the offset c_{OFF} based on magnetic vectors m₁ to m_{N} and angular velocity vectors ω₁ to ω_{N} represented by N magnetic data M₁ to M_{N} and N angular velocity data W₁ to W_{N} respectively output from the three-dimensional magnetic sensor 50 and the three-dimensional angular velocity sensor 60 on a unit time Δt basis from a time T=1 to a time T=N.

Meanwhile, the three-dimensional magnetic sensor 50, the three-dimensional angular velocity sensor 60, and a memory unit 300 are also shown in the function block diagram of FIG. 5 in addition to the offset estimation apparatus 100 for the convenience of description.

In addition, hereinafter, the distribution shape determination unit 150 will also be referred to as a first determination unit and the accuracy determination unit 130 will also be referred to as a second determination unit.

The attitude calculation unit 110 calculates an attitude variation of an attitude Aₖ of the portable equipment 1 at each time T=k (k=1, 2, . . . , N) from a reference attitude (attitude A₁), which is an attitude A₁ of the portable equipment 1 at a time T=1, based on an angular velocity vector ω indicated by angular velocity data W output from the three-dimensional angular velocity sensor 60 and periodically outputs attitude data, which are data representing the calculated attitude variation.

In this embodiment, the attitude A and the attitude variation are expressed using a rotation matrix of 3×3 (for example, direct cosine matrix). Hereinafter, a rotation matrix representing an attitude variation from the reference attitude (attitude A₁) to the attitude Aₖ will be referred to as an attitude rotation matrix Rₖ.

The attitude calculation unit 110 calculates an attitude rotation matrix Rₖ at each time T=k (k=1, 2, . . . , N) based on Equation (1) and Equation (2) below and outputs the calculated attitude rotation matrix Rₖ. Meanwhile, a matrix I_{3×3} present in Equation (1) is a unit matrix of 3×3. In addition, an operator Ω present in Equation (2) is an operator for converting a three-dimensional vector p shown in Equation (4) into an alternating matrix of 3×3 present at the right side of Equation (3) as shown in Equation (3).

$$\begin{matrix}{R}_{1} = {I}_{3 \times 3} & Equation ( 1 ) \\ {R}_{k} = {R}_{k - 1} {\{ exp ( Ω ( {ω}_{k - 1} ) Δ t ) \}}^{T} ( k = 2 , … , N ) & Equation ( 2 ) \\ Ω ( p ) = [ \begin{matrix}0 & - {p}_{z} & {p}_{y} \\ {p}_{z} & 0 & - {p}_{x} \\ - {p}_{y} & {p}_{x} & 0\end{matrix} ] & Equation ( 3 ) \\ p = {[ \begin{matrix}{p}_{x} & {p}_{y} & {p}_{z}\end{matrix} ]}^{T} & Equation ( 4 )\end{matrix}$$

Although, in this embodiment, the attitude A₁ is a reference attitude, the reference attitude is not particularly restricted so long as an attitude variation of an attitude Aₖ at each time T=k (k=1, 2, . . . , N) from the reference attitude can be calculated based on angular velocity data W.

For example, the reference attitude may be any one of the attitude A₂ to the attitude A_{N}.

The N attitude data (that is, N attitude rotation matrices R₁ to R_{N}) generated by the attitude calculation unit 110 are stored in the memory unit 300. The memory unit 300 corresponds to the RAM 20 shown in FIG. 1.

In addition, the N magnetic data M₁ to M_{N} (that is, N magnetic vectors m₁ to m_{N}) output from the three-dimensional magnetic sensor 50 are also stored in the memory unit 300 in addition to the N attitude rotation matrices R₁ to R_{N}.

The accuracy determination unit 130 performs an accuracy determination process using the attitude rotation matrices R₁ to R_{N} stored in the memory unit 300.

The accuracy determination process is a process of determining whether or not, in a case in which the offset calculation unit 140 calculates an estimation value c_{E} of the offset c_{OFF} based on the attitude rotation matrices R₁ to R_{N} and the magnetic vectors m₁ to m_{N} stored in the memory unit 300, accuracy of the calculation is high. The accuracy determination process will hereinafter be described in detail.

In a case in which the result of the determination performed by the accuracy determination unit 130 is positive, the offset calculation unit 140 calculates an estimation value c_{E} of the offset c_{OFF} and a reference estimated geomagnetic vector r_{E1} based on the attitude rotation matrices R₁ to R_{N} and the magnetic vectors m₁ to m_{N} stored in the memory unit 300. Meanwhile, the reference estimated geomagnetic vector r_{E1} will hereinafter be described.

Meanwhile, the process of calculating the estimation value c_{E} of the offset c_{OFF} performed by the offset calculation unit 140 may also be referred to as an offset calculation process.

The distribution shape determination unit 150 performs a distribution determination process using the attitude rotation matrices R₁ to R_{N} and the magnetic vectors m₁ to m_{N} stored in the memory unit 300 and the reference estimated geomagnetic vector r_{E1} calculated by the offset calculation unit 140.

The distribution determination process is a process of determining whether or not, in a case in which the offset calculation unit 140 calculates an estimation value C_{E} of the offset c_{OFF} based on the attitude rotation matrices R₁ to R_{N} and the magnetic vectors m₁ to m_{N} stored in the memory unit 300, the estimation value c_{E} of the offset c_{OFF} calculated by the offset calculation unit 140 correctly represents the offset c_{OFF}. The distribution determination process will hereinafter be described in detail.

In a case in which the result of the determination performed by the distribution shape determination unit 150 is positive, the adoption unit 160 adopts the estimation value c_{E} of the offset c_{OFF} calculated by the offset calculation unit 140 as the offset c_{OFF}. In a case in which the result of the determination performed by the distribution shape determination unit 150 is negative, the adoption unit 160 does not adopt the estimation value c_{E} as the offset c_{OFF}.

Although, in this embodiment, the offset calculation unit 140 calculates the estimation value c_{E} of the offset c_{OFF} and the reference estimated geomagnetic vector r_{E1} only in a case in which the result of the determination performed by the accuracy determination unit 130 is positive, the present invention is not limited to this embodiment.

For example, the offset calculation unit 140 may calculate the estimation value c_{E} of the offset c_{OFF} or else irrespective of the result of the determination performed by the accuracy determination unit 130. In this case, the adoption unit 160 may adopt the estimation value c_{E} of the offset c_{OFF} calculated by the offset calculation unit 140 as the offset c_{OFF} only in a case in which the result of the determination performed by the accuracy determination unit 130 is positive and the result of the determination performed by the distribution shape determination unit 150 is positive.

Hereinafter, the offset calculation process, the distribution determination process, and the accuracy determination process as described above will be described in detail.

### 2. OFFSET CALCULATION PROCESS

As described above, the offset calculation process performed by the offset calculation unit 140 is a process of calculating an estimation value c_{E} of the offset c_{OFF}. First, the offset calculation process performed by the offset calculation unit 140 will hereinafter be described in detail.

As shown in FIG. 4, the vector ^{S}B_{g}(Aₖ) representing the geomagnetism B_{g} is a vector obtained by subtracting the offset c_{OFF} of the three-dimensional magnetic sensor 50 from the magnetic vector mₖ indicated by the magnetic data Mₖ output from the three-dimensional magnetic sensor 50 and may be represented by Equation (5) below. Meanwhile, hereinafter, the vector ^{S}B_{g}(Aₖ) representing the geomagnetism B_{g} observed in the sensor coordinate system Σ_{S} will also be expressed as an observed geomagnetic vector rₖ. In addition, the vector ^{S}B_{g}(A₁) representing the geomagnetism B_{g} observed in the sensor coordinate system Σ_{S} when the offset estimation apparatus 100 is at the reference attitude will also be expressed as a reference observed geomagnetic vector r₁. The observed geomagnetic vector rₖ is a three-dimensional vector representing the geomagnetism B_{g} in the sensor coordinate system Σ_{S} when the attitude of the portable equipment 1 is the attitude Aₖ and the reference observed geomagnetic vector r₁ is a three-dimensional vector representing the geomagnetism B_{g} in the sensor coordinate system Σ_{S} when the attitude of the portable equipment 1 is the attitude A₁. Consequently, the observed geomagnetic vector rₖ is represented as a vector obtained by rotating the reference observed geomagnetic vector r₁ according to a transposed matrix of the attitude rotation matrix Rₖ representing the change of attitude from the attitude A₁ to the attitude Aₖ as represented by Equation (6) below. Equation (7) may be derived from Equations (5) and (6).

^{S}B_{g}(Aₖ)=mₖ−c_{OFF} (k=1, . . . , N) Equation (5)

^{S}B_{g}(Aₖ)=rₖ=Rₖ^{T}r₁ (k=1, . . . , N) Equation (6)

mₖ=Rₖ^{T}r₁+c_{OFF} (k=1, . . . , N) Equation (7)

Meanwhile, Equation (7) comes into effect only in an ideal case, i.e. in a case in which the three-dimensional magnetic sensor 50 can detect a magnetic field without an error and, in addition, the magnetic vector mₖ output from the three-dimensional magnetic sensor 50 completely coincides with the detected magnetic field. In a case in which Equation (7) comes into effect, therefore, it is possible to calculate the offset c_{OFF} as a solution of a simultaneous linear equation set by Equation (7).

However, the magnetic data M output from the three-dimensional magnetic sensor 50 have a measurement error and, generally, the left side and the right side of Equation (7) do not coincide with each other. For this reason, it is not possible to calculate the offset c_{OFF} as the solution of the simultaneous linear equation set based on Equation (7).

In the offset calculation process according to this embodiment, therefore, an objective function f(x) shown in Equation (8) below is introduced to calculate an estimation value (approximate value) of the offset c_{OFF} and an estimation value (approximate value) of the reference observed geomagnetic vector r₁ using a statistical method such that the left side and the right side of Equation (7) have as approximate values as possible.

The objective function f(x) is a function representing a degree of error magnitude between first variable vectors g₁ to g_{N} and second variable vectors d₁ to d_{N}. Specifically, the objective function f(x) represents an average of squared values of the magnitudes of vectors obtained by subtracting the second variable vectors dₖ from the first variable vectors gₖ as represented by Equation (8) below.

Here, a variable vector x, which is a variable of the objective function f(x), is a six-dimensional variable vector having a three-dimensional variable vector c representing the offset c_{OFF} (hereinafter, also referred to as an offset variable vector c) and a three-dimensional variable vector r representing the reference observed geomagnetic vector r₁ (hereinafter, also referred to as a reference variable vector r) as elements as represented by Equation (9) below. Namely, the objective function may be a function having, as a variable, a variable vector including each element of a reference variable vector, which is a variable representing the geomagnetism in the rectangular coordinate system when the attitude of the equipment is the reference attitude and each element of the offset variable vector as elements. In addition, the first variable vector gₖ is a three-dimensional variable vector representing the vector ^{S}B_{g}(Aₖ) as represented by Equation (10). Namely, a variable representing the geomagnetism in the rectangular coordinate system when the attitude of the equipment is the reference attitude may be defined as a reference variable vector and the first variable vector may be a vector representing the reference variable vector in the rectangular coordinate system when the attitude of the equipment is changed from the reference attitude by the attitude variation. In addition, the second variable vectors dₖ is a three-dimensional variable vector representing the vector obtained by subtracting the offset variable vector c from the magnetic vector mₖ as represented by Equation (11).

It is possible to calculate a value considerable (plausible) as the offset c_{OFF} and a value considerable (plausible) as the reference observed geomagnetic vector r₁ by calculating the variable vector x minimizing such an objective function f(x) (that is, the offset variable vector c and the reference variable vector r to minimize the objective function f(x)).

Meanwhile, hereinafter, a vector obtained by adding the offset variable vector c to the first variable vector gₖ will also be referred to as a detected magnetic variable vector.

$$\begin{matrix}f ( x ) = \frac{1}{N} {\sum }_{k = 1}^{N} {‖ {g}_{k} - {d}_{k} ‖}^{2} & Equation ( 8 ) \\ x = {[ \begin{matrix}{r}^{T} & {c}^{T}\end{matrix} ]}^{T} & Equation ( 9 ) \\ {g}_{k} = {R}_{k}^{T} r ( k = 1 , … , N ) & Equation ( 10 ) \\ {d}_{k} = {m}_{k} - c ( k = 1 , … , N ) & Equation ( 11 )\end{matrix}$$

Hereinafter, a method of calculating the variable vector x minimizing the objective function f(x) represented by Equation (8) will be described in detail.

In this embodiment, first, the objective function f(x) is converted into an objective function g(x) represented by Equation (12) below. The objective function g(x) is a function obtained by expressing the objective function f(x) in a quadratic form having each element of the variable vector x as a variable and, in addition, deleting a constant term which does not affect minimization of the objective function f(x). The variable vector x minimizing such an objective function g(x) is equivalent to the variable vector x minimizing the objective function f(x). That is, minimization of the objective function f(x) may result in minimization of the objective function g(x).

Here, a matrix Q present in Equation (12) is a coefficient matrix of the objective function g(x), which is a quadratic form. Specifically, the matrix Q is a positive definite symmetric matrix of 6×6 represented by Equation (13). A vector b present in Equation (12) is a six-dimensional vector represented by Equation (15). A matrix R_{AVE} present in Equation (13) is a matrix of 3×3 represented by Equation (14). A vector b_{R} present in Equation (15) is a three-dimensional vector represented by Equation (16). A vector m present in Equation (15) is a three-dimensional vector represented by Equation (17).

$$\begin{matrix}g ( x ) = {x}^{T} Qx - 2 {b}^{T} x & Equation ( 12 ) \\ Q = [ \begin{matrix}{I}_{3 \times 3} & {R}_{AVE} \\ {R}_{AVE}^{T} & {I}_{3 \times 3}\end{matrix} ] & Equation ( 13 ) \\ {R}_{AVE} = \frac{1}{N} {\sum }_{k = 1}^{N} {R}_{k} & Equation ( 14 ) \\ b = [ \begin{matrix}{b}_{R} \\ {m}_{AVE}\end{matrix} ] & Equation ( 15 ) \\ {b}_{R} = \frac{1}{N} {\sum }_{k = 1}^{N} {R}_{k} {m}_{k} & Equation ( 16 ) \\ {m}_{AVE} = \frac{1}{N} {\sum }_{k = 1}^{N} {m}_{k} & Equation ( 17 )\end{matrix}$$

Hereinafter, the variable vector x minimizing the objective function g(x) represented by Equation (12) will also be referred to as an optimal solution x_{OPT}. In a case in which Equation (13) is a positive definite matrix, the optimal solution x_{OPT} may be calculated by Equation (18) below. In addition, the optimal solution x_{OPT} has the reference estimated geomagnetic vector r_{E1} and the estimation value c_{E} of the offset c_{OFF} as elements as represented by Equation (19) below. Here, the reference estimated geomagnetic vector r_{E1} is an estimation value of the reference geomagnetic vector r₁.

Consequently, it is possible for the offset calculation unit 140 to calculate the estimation value c_{E} of the offset c_{OFF} by extracting an element corresponding to the estimation value c_{E} represented by Equation (19) from the optimal solution x_{OPT} calculated by Equation (18).

x_{OPT}=Q⁻¹b Equation (18)

x_{OPT}=[e_{E1}^{T}c_{E}^{T}]^{T} Equation (19)

Meanwhile, in a case in which the result of the determination performed by the accuracy determination unit 130, which will hereinafter be described, is negative, the offset calculation unit 140 does not perform the above operations, i.e. a series of operations to calculate the estimation value c_{E} of the offset.

In conclusion, the offset calculation process is a process of: setting a predetermined number of vectors representing geomagnetism when the attitude of the equipment is changed from the reference attitude to a predetermined number of attitudes in the rectangular coordinate system based on angular velocity data; setting a predetermined number of vectors (not including an offset) representing a predetermined number of geomagnetisms corresponding to change of the attitude based on magnetic data; and diminishing errors of the predetermined vectors representing the respective geomagnetisms to calculate the offset.

The present invention may also provide an offset estimation apparatus provided at equipment including a three-dimensional angular velocity sensor for periodically detecting angular velocities in three directions and for sequentially outputting detection results as angular velocity data and a three-dimensional magnetic sensor for periodically detecting magnetic components in three directions including geomagnetism and for sequentially outputting detection results as magnetic data, which are vector data in a three-axis rectangular coordinate system, to calculate an estimation value of an offset of the three-dimensional magnetic sensor, wherein the offset estimation apparatus includes an attitude calculation unit for periodically calculating an attitude variation of the equipment from a reference attitude based on the angular velocity data, a variable vector representing the geomagnetism in the rectangular coordinate system when the attitude of the equipment is the reference attitude being defined as a reference variable vector, a vector obtained by changing the reference variable vector by the attitude variation being defined as a first variable vector, a variable vector obtained by adding the first variable vector to an offset variable vector, which is a variable vector representing the offset, being defined as a detected magnetic variable vector, and an offset calculation unit for calculating the offset variable vector minimizing an error between a predetermined number of points in the rectangular coordinate system indicated by a predetermined number of the detected magnetic variable vectors respectively corresponding to a predetermined number of the attitude variations calculated by the attitude calculation unit and a predetermined number of points in the rectangular coordinate system indicated by a predetermined number of magnetic data output from the three-dimensional magnetic sensor as the estimation value of the offset.

### 3. DISTRIBUTION DETERMINATION PROCESS

Next, the distribution determination process will be described.

As previously described, the distribution determination process performed by the distribution shape determination unit 150 is a process of determining whether or not, in a case in which the offset calculation unit 140 calculates an estimation value c_{E} of the offset c_{OFF} based on the magnetic vectors m₁ to m_{N} stored in the memory unit 300, the estimation value c_{E} correctly represents the offset c_{OFF}. In other words, the distribution determination process is a process of determining whether or not the magnetic vectors m₁ to m_{N} stored in the memory unit 300 are data suitable for calculating the estimation value c_{E} of the offset c_{OFF}.

The offset calculation process as described above is a process performed on the premise that corrected magnetic vectors r₁ to r_{N} are vectors of equal length having the point C_{G} as the start point (the initial point) in the sensor coordinate system Σ_{S} as shown in FIG. 4, i.e. the distribution shape of a plurality of points on the sensor coordinate system Σ_{S} indicated by the magnetic vectors m₁ to m_{N} can be regarded as a spherical surface. That the offset calculation process is performed on the above premise is also obvious from that the observed geomagnetic vector rₖ is represented as a vector obtained by rotating the reference observed geomagnetic vector r₁ according to the attitude rotation matrix Rₖ, which is a rotation matrix, as represented by Equation (6).

In a practical sense, however, the distribution shape of a plurality of points on the sensor coordinate system Σ_{S} indicated by the magnetic vectors m₁ to m_{N} may be a distorted shape different from a spherical surface. In this case, even if the offset calculation unit 140 calculates an estimation value c_{E} of the offset c_{OFF} based on the magnetic vectors m₁ to m_{N}, there is a high possibility that the estimation value c_{E} may be a value greatly deviating from the offset c_{OFF}.

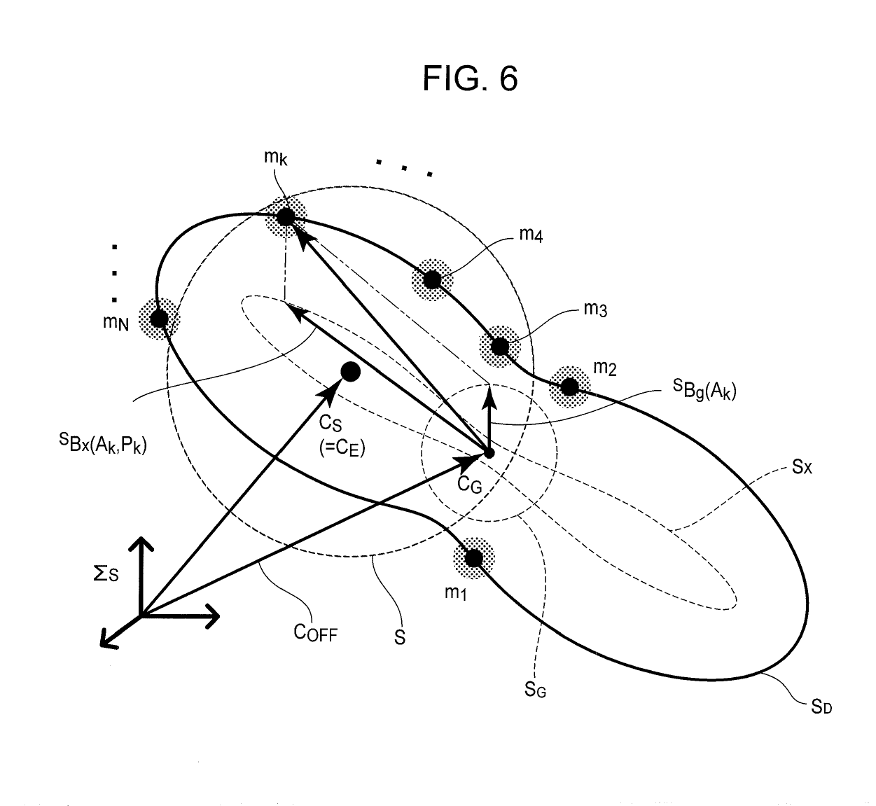

For example, as shown in FIG. 6, a magnetic field (hereinafter, also referred to as a noise magnetic field Bₓ) expressed as a vector ^{S}Bₓ(A, P), the direction and magnitude of which are changed according to change in the attitude A and the position P of the portable equipment 1, may be detected by the three-dimensional magnetic sensor 50 in addition to the geomagnetism B_{g} and the internal magnetic field Bᵢ. In this case, the magnetic vector mₖ represents the sum of the vector ^{S}Bᵢ, the vector ^{S}B_{g}(Aₖ), and a vector ^{S}Bₓ(Aₖ, Pₖ). When the position P is changed from P₁ to P_{N}, there is a high possibility that a curved surface indicated by the vector ^{S}Bₓ(Aₖ, Pₖ) may have a distorted shape different from a spherical surface as shown in FIG. 6. In this case, therefore, there is a high possibility that a plurality of points on the sensor coordinate system Σ_{S} indicated by the magnetic vectors m₁ to m_{N} may not be distributed in the vicinity of the spherical surface S_{G} but may be distributed in the vicinity of the surface of a solid S_{D} having a shape different from the spherical surface.

And even in a case in which a plurality of points on the sensor coordinate system Σ_{S} indicated by the magnetic vectors m₁ to m_{N} is distributed in the vicinity of the surface of the solid S_{D} having a shape different from the spherical surface like as in an example shown in FIG. 6, the offset calculation unit 140 calculates the coordinates of a center point Cs of a spherical surface S as the estimation value c_{E} of the offset c_{OFF}, which is coordinates of the center point C_{S} of the spherical surface S_{G} on the assumption that the points are distributed in the vicinity of the spherical surface and, in addition, the spherical surface S coincides with the spherical surface S_{G}.

In a practical sense, however, the magnetic vectors m₁ to m_{N} shown in FIG. 6 represent a magnetic field obtained by adding the noise magnetic field Bₓ in addition to the internal magnetic field Bᵢ and the geomagnetism B_{g}. Consequently, in a case in which the noise magnetic field B_{X} exists, i.e. in a case in which a plurality of points on the sensor coordinate system Σ_{S} indicated by the magnetic vectors m₁ to m_{N} is distributed in the vicinity of the surface of the solid S_{D}, there is a high possibility that the spherical surface S having the points in the vicinity thereof may be a spherical surface different from the spherical surface S_{G} and there is a high possibility that the center point Cₛ of the spherical surface S may have coordinates different from the center point C_{G} of the spherical surface S_{g}.

That is, in a case in which a plurality of points on the sensor coordinate system Σ_{S} indicated by the magnetic vectors m₁ to m_{N} is distributed in the vicinity of the surface of the solid S_{D}, there is a high possibility that the estimation value c_{E} calculated as the coordinates of the center point Cₛ of the spherical surface S may not correctly represent the offset c_{OFF}.

For this reason, the distribution shape determination unit 150 determines whether or not the distribution shape of a plurality of points on the sensor coordinate system Σ_{S} indicated by the magnetic vectors m₁ to m_{N} can be regarded as a spherical surface (that is, whether the distribution shape is not a distorted shape) based on the magnetic vectors m₁ to m_{N}, the attitude rotation matrices R₁ to R_{N}, and the reference estimated geomagnetic vector r_{E1} calculated by the offset calculation unit 140 to determine whether or not the estimation value c_{E} of the offset c_{OFF} calculated by the offset calculation unit 140 based on magnetic vectors m₁ to m_{N} correctly represents the offset c_{OFF}.

As a result, in a case in which the offset calculation unit 140 calculates the estimation value c_{E} of the offset c_{OFF} based on the magnetic vectors m₁ to m_{N} not suitable for calculating the estimation value c_{E} of the offset c_{OFF}, i.e. the magnetic vectors m₁ to m_{N} containing noise, it is possible to determine that the calculated value does not correctly represent the offset c_{OFF}.

Hereinafter, the distribution determination process performed by the distribution shape determination unit 150 will be described in detail.

As shown in FIG. 5, the distribution shape determination unit 150 includes a first matrix calculation unit 152, a second matrix calculation unit 154, and a similarity determination unit 156.

The first matrix calculation unit 152 calculates a matrix S represented by Equation (20) below based on the magnetic vectors m₁ to m_{N} stored in the memory unit 300. Here, a vector sₖ present in Equation (20) is a three-dimensional vector represented by Equation (21) below and the matrix S is a symmetric matrix of 3×3 represented by Equation (21) below showing distribution of the magnetic vectors m₁ to m_{N} in the sensor coordinate system Σ_{S}. Hereinafter, the matrix S will also be referred to as a magnetic data distribution matrix.

$$\begin{matrix}S = \frac{1}{N} {\sum }_{k = 1}^{N} {s}_{k} {s}_{k}^{T} & Equation ( 20 ) \\ {s}_{k} = {m}_{k} - {m}_{AVE} ( k = 1 , … , N ) & Equation ( 21 )\end{matrix}$$

The second matrix calculation unit 154 calculates a matrix E represented by Equation (25) below based on the attitude rotation matrices R₁ to R_{N} stored in the memory unit 300 and the reference estimated geomagnetic vector r_{E1} calculated by the offset calculation unit 140.

Specifically, first, the reference estimated geomagnetic vector r_{E1} is rotated according to the attitude rotation matrix Rₖ to calculate an estimated geomagnetic vector r_{Ek}, which is a three-dimensional vector, as represented by Equation (22) below. Next, an average of estimated geomagnetic vectors r_{E1} to r_{EN} is calculated to calculate a vector r_{EAVE}, which is a three-dimensional vector, as represented by Equation (23) below. In addition, a vector eₖ, which is a three-dimensional vector, based on the vector r_{EAVE} and the estimated geomagnetic vector r_{Ek} as represented by Equation (24) below. And a matrix E, which is a symmetric matrix of 3×3, is calculated based on the vector eₖ as represented by Equation (25) below.

Here, the matrix E is a matrix representing distribution of the estimated geomagnetic vector r_{Ek} as obvious from Equation (23) to Equation (25) below. Hereinafter, the matrix E will also be referred to as an estimated geomagnetic data distribution matrix.

$$\begin{matrix}{r}_{Ek} = {R}_{k}^{T} {r}_{E 1} ( k = 1 , … , N ) & Equation ( 22 ) \\ {r}_{EAVE} = \frac{1}{N} {\sum }_{k = 1}^{N} {r}_{Ek} & Equation ( 23 ) \\ {e}_{k} = {r}_{Ek} - {r}_{EAVE} ( k = 1 , … , N ) & Equation ( 24 ) \\ E = \frac{1}{N} {\sum }_{k = 1}^{N} {e}_{k} {e}_{k}^{T} & Equation ( 25 )\end{matrix}$$

In a case in which the influence of the noise magnetic field Bₓ is negligibly small, a point on the sensor coordinate system Σ_{S} indicated by a vector obtained by adding the vector representing the estimation value c_{E} of the offset c_{OFF} to the reference estimated geomagnetic vector r_{E1} can be regarded as coinciding with a point on the sensor coordinate system Σ_{S} indicated by the magnetic vector m₁.

In addition, the estimated geomagnetic vector r_{Ek} is an estimation value (approximate value) of the observed geomagnetic vector rₖ, which is a vector obtained by rotating the reference estimated geomagnetic vector r_{E1}, which is an estimation value of the reference observed geomagnetic vector r₁, according to the attitude rotation matrix Rₖ and a vector obtained by rotating the reference observed geomagnetic vector r₁ according to the attitude rotation matrix Rₖ. In a case in which the influence of the noise magnetic field Bₓ is negligibly small, therefore, a point on the sensor coordinate system Σ_{S} indicated by a vector obtained by adding the vector representing the estimation value c_{E} of the offset c_{OFF} to the estimated geomagnetic vector r_{Ek} can be regarded as coinciding with a point on the sensor coordinate system Σ_{S} indicated by the magnetic vector mₖ.

That is, if the influence of the noise magnetic field Σₓ is negligibly small and the distribution shape of a plurality of points on the sensor coordinate system Σ_{S} indicated by the magnetic vectors m₁ to m_{N} can be regarded as a spherical surface, the distribution shape of a plurality of points on the sensor coordinate system Σ_{S} indicated by the estimated geomagnetic vectors r_{E1} to r_{EN} can be regarded as coinciding with the distribution shape of a plurality of points on the sensor coordinate system Σ_{S} indicated by the magnetic vectors m₁ to m_{N}.

In addition, in a case in which the influence of the noise magnetic field Bₓ is large, there is a high possibility that the distribution shape of a plurality of points on the sensor coordinate system Σ_{S} indicated by the magnetic vectors m₁ to m_{N} may be a distorted shape different from a spherical surface. Even in this case, on the other hand, the distribution shape of a plurality of points on the sensor coordinate system Σ_{S} indicated by the estimated geomagnetic vectors r_{E1} to r_{EN} is a spherical surface.

That is, in a case in which the influence of the noise magnetic field Bₓ is negligibly small, the distribution shape of a plurality of points on the sensor coordinate system Σ_{S} indicated by the estimated geomagnetic vectors r_{E1} to r_{EN} can be regarded as coinciding with the distribution shape of a plurality of points on the sensor coordinate system Σ_{S} indicated by the magnetic vectors m₁ to m_{N}. In a case in which the influence of the noise magnetic field Bₓ is large, however, the two distribution shapes are different from each other.

Consequently, it is possible to estimate a degree of influence of the noise magnetic field Bₓ based on a degree of difference between the distribution shape of a plurality of points on the sensor coordinate system Σ_{S} indicated by the estimated geomagnetic vectors r_{E1} to r_{EN} and the distribution shape of a plurality of points on the sensor coordinate system Σ_{S} indicated by the magnetic vectors m₁ to m_{N}. That is, it is possible to determine whether or not the estimation value c_{E} of the offset c_{OFF} calculated by the offset calculation unit 140 correctly represents the offset c_{OFF} by determining whether or not a degree of difference between the two distribution shapes is within a predetermined range, i.e. the two distribution shapes can be regarded as coinciding with each other.

Meanwhile, determination as to whether or not a degree of difference between the distribution shape of a plurality of points on the sensor coordinate system Σ_{S} indicated by the estimated geomagnetic vectors r_{E1} to r_{EN} and the distribution shape of a plurality of points on the sensor coordinate system Σ_{S} indicated by the magnetic vectors m₁ to m_{N} is within a predetermined range may be performed using any method.

In this embodiment, as an example, determination as to whether or not the two distribution shapes can be regarded as coinciding with each other is performed by determining whether or not the matrix E and the matrix S can be regarded as coinciding with each other.

Specifically, the similarity determination unit 156 determines whether or not a degree of difference between a component of the matrix E representing distribution of the estimated geomagnetic vector r_{Ek} and a component of the matrix S representing distribution of the magnetic vectors m₁ to m_{N} is within a predetermined range (determines whether or not the matrix E and the matrix S coincide with each other or are similar to each other) to determine whether or not a degree of difference between the distribution shape of a plurality of points on the sensor coordinate system Σ_{S} indicated by the estimated geomagnetic vectors r_{E1} to r_{EN} and the distribution shape of a plurality of points on the sensor coordinate system Σ_{S} indicated by the magnetic vectors m₁ to m_{N} is within a predetermined range and thus to determine whether or not the estimation value c_{E} of the offset c_{OFF} calculated by the offset calculation unit 140 correctly represents the offset c_{OFF}.

Hereinafter, a specific determination method will be described.

Three eigenvalues of the matrix E are defined as a maximum eigenvalue λ_{E, MAX}, a middle eigenvalue λ_{E, MID}, and a minimum eigenvalue λ_{E, MIN} in order of size and three normalized eigenvectors corresponding to the respective eigenvalues are defined as an eigenvector u_{E, MAX}, an eigenvector u_{E, MID}, and an eigenvector u_{E, MIN}.

In addition, three eigenvalues of the matrix S are defined as a maximum eigenvalue λ_{S, MAX}, a middle eigenvalue λ_{S, MID}, and a minimum eigenvalue λ_{S, MIN} in order of size and three normalized eigenvectors corresponding to the respective eigenvalues are defined as an eigenvector u_{S, MAX}, an eigenvector u_{S, MID}, and an eigenvector u_{S, MIN}.

In a case in which the matrix E and the matrix S can be regarded as coinciding with each other, the maximum eigenvalue λ_{E, MAX}, the middle eigenvalue λ_{E, MID}, and the minimum eigenvalue λ_{E, MIN} can be regarded as being equivalent to the maximum eigenvalue λ_{S, MAX}, the middle eigenvalue λ_{S, MID}, and the minimum eigenvalue λ_{S, MIN}, respectively. In addition, the eigenvector u_{E, MAX}, the eigenvector u_{E, MID}, and the eigenvector u_{E, MIN} can be regarded as being equivalent to the eigenvector u_{S, MAX}, the eigenvector u_{S, MID}, and the eigenvector u_{S, MIN}, respectively.

That is, in a case in which the matrix E and the matrix S satisfy a first determination condition represented by Equation (26) below, a second determination condition represented by Equation (27) below, a third determination condition represented by Equation (28) below, a fourth determination condition represented by Equation (29) below, a fifth determination condition represented by Equation (30) below, and a sixth determination condition represented by Equation (31) below, the matrix E and the matrix S can be regarded as coinciding with each other.

Here, a first threshold value α₁, a second threshold value α₂, and a third threshold value α₃ present in Equation (26) to Equation (28) are real numbers greater than 0 and less than 1 and a fourth threshold value α₄, a fifth threshold value α₅, and a sixth threshold value α₆ present in Equation (29) to Equation (31) are real numbers equal to or greater than 1.

Meanwhile, the first determination condition to the third determination condition may be conditions other than the conditions represented by Equation (26) to Equation (28) below so long as the first determination condition to the third determination condition are conditions representing that directions indicated by two eigenvectors are parallel to each other or an angle between the two eigenvectors is equal to or less than a predetermined angle.

In addition, the fourth determination condition to the sixth determination condition may be conditions other than the conditions represented by Equation (29) to Equation (31) below so long as the fourth determination condition to the sixth determination condition are conditions representing that two eigenvectors are equal to each other or are regarded as being equal to each other or an index value representing a degree of approximation between the two eigenvectors is equal to or greater than a threshold value. For example, that an absolute value of a difference value between two eigenvectors is equal to or less than a predetermined threshold value may be set as a condition.

$$\begin{matrix}\vert {u}_{E , MAX} \cdot {u}_{S , MAX} \vert \geq {α}_{1} & Equation ( 26 ) \\ \vert {u}_{E , MID} \cdot {u}_{S , MID} \vert \geq {α}_{2} & Equation ( 27 ) \\ \vert {u}_{E , MIN} \cdot {u}_{S , MIN} \vert \geq {α}_{3} & Equation ( 28 ) \\ \frac{1}{{α}_{4}} \leq \frac{{λ}_{S , MAX}}{{λ}_{E , MAX}} \leq {α}_{4} & Equation ( 29 ) \\ \frac{1}{{α}_{5}} \leq \frac{{λ}_{S , MID}}{{λ}_{E , MID}} \leq {α}_{5} & Equation ( 30 ) \\ \frac{1}{{α}_{6}} \leq \frac{{λ}_{S , MIN}}{{λ}_{E , MIN}} \leq {α}_{6} & Equation ( 31 )\end{matrix}$$

First, the similarity determination unit 156 calculates three eigenvalues λ_{E, MAX}, λ_{E, MID}, and λ_{E, MIN} and three eigenvectors u_{E, MAX}, u_{E, MID}, and u_{E, MIN} of the matrix E and three eigenvalues λ_{S, MAX}, λ_{S, MID}, and λ_{S, MIN} and three eigenvectors u_{S, MAX}, u_{S, MID}, and u_{S, MIN} of the matrix S. And the similarity determination unit 156 determines whether or not the calculated eigenvalues and eigenvectors satisfy all of the first to sixth determination conditions represented by Equation (26) to Equation (31).

In a case in which the determination result is positive, the matrix E and the matrix S can be regarded as coinciding with each other. In this case, the distribution shape of a plurality of points on the sensor coordinate system Σ_{S} indicated by the estimated geomagnetic vectors r_{E1} to r_{EN} and the distribution shape of a plurality of points on the sensor coordinate system Σ_{S} indicated by the magnetic vectors m₁ to m_{N} can be regarded as coinciding with each other and the distribution shape of a plurality of points on the sensor coordinate system Σ_{S} indicated by the magnetic vectors m₁ to M_{N} can be regarded as a spherical surface. Consequently, the estimation value c_{E} of the offset c_{OFF} calculated by the offset calculation unit 140 can be regarded as correctly representing the offset c_{OFF}.

On the other hand, in a case in which the determination result is negative, the distribution shape of a plurality of points on the sensor coordinate system Σ_{S} indicated by the magnetic vectors m₁ to m_{N} is a distorted shape different from a spherical surface. Consequently, there is a high possibility that the estimation value c_{E} of the offset c_{OFF} calculated by the offset calculation unit 140 may not correctly represent the offset c_{OFF}.

In this way, it is possible for the similarity determination unit 156 to determine whether or not the estimation value c_{E} of the offset c_{OFF} calculated by the offset calculation unit 140 based on the magnetic vectors m₁ to m_{N} stored in the memory unit 300 correctly represents the offset c_{OFF} by determining whether or not the matrix E and the matrix S satisfy the first determination condition to the sixth determination condition.

Although, in this embodiment, the similarity determination unit 156 determines whether or not the matrix E and the matrix S satisfy all of the first to sixth determination conditions represented by Equation (26) to Equation (31), the present invention is not limited thereto. The similarity determination unit 156 may determine whether or not the matrix E and the matrix S satisfy at least some of the first to sixth determination conditions.

Even in a case in which the matrix E and the matrix S satisfy at least some of the first to sixth determination conditions, the matrix E and the matrix S can be regarded as coinciding with each other. Consequently, it is possible for the similarity determination unit 156 to determine whether or not the estimation value c_{E} of the offset c_{OFF} calculated by the offset calculation unit 140 correctly represents the offset c_{OFF}.

Meanwhile, hereinafter, determination as to whether or not the matrix E and the matrix S can be regarded as coinciding with each other, i.e. determination as to whether or not the distribution shape of a plurality of points on the sensor coordinate system Σ_{S} indicated by the estimated geomagnetic vectors r_{E1} to r_{EN} and the distribution shape of a plurality of points on the sensor coordinate system Σ_{S} indicated by the magnetic vectors m₁ to m_{N} can be regarded as coinciding with each other, will also be referred to as a first determination.

In addition, in the offset estimation apparatus as described above, a variable vector representing the geomagnetism in the rectangular coordinate system when the equipment is at the reference attitude may be defined as a reference variable vector, the reference variable vector minimizing the objective function may be defined as a reference estimated geomagnetic vector, and a vector obtained by changing the reference estimated geomagnetic vector by the attitude variation may be defined as an estimated geomagnetic vector, and the offset estimation apparatus may include a first determination unit for determining whether or not a degree of difference between a distribution shape of a predetermined number of points in the rectangular coordinate system indicated by a predetermined number of the estimated geomagnetic vectors respectively corresponding to a predetermined number of attitude variations calculated by the attitude calculation unit and a distribution shape of a predetermined number of points in the rectangular coordinate system indicated by a predetermined number of magnetic data output from the three-dimensional magnetic sensor is within a predetermined range and an offset adoption unit for adopting the estimation value of the offset as the offset in a case in which a determination result of the first determination unit is positive.

In addition, in the offset estimation apparatus as described above, a variable vector representing the geomagnetism in the rectangular coordinate system when the equipment is at the reference attitude may be defined as a reference variable vector, the reference variable vector minimizing the objective function may be defined as a reference estimated geomagnetic vector, and a vector obtained by changing the reference estimated geomagnetic vector by the attitude variation may be defined as an estimated geomagnetic vector, and the offset estimation apparatus may include a first determination unit for determining whether or not a degree of difference between a component of an estimated geomagnetic data distribution matrix representing distribution of a predetermined number of the estimated geomagnetic vectors respectively corresponding to a predetermined number of attitude variations calculated by the attitude calculation unit and a component of an magnetic data distribution matrix representing distribution of a predetermined number of magnetic data output from the three-dimensional magnetic sensor is within a predetermined range and an offset adoption unit for adopting the estimation value of the offset as the offset in a case in which a determination result of the first determination unit is positive.

In addition, in the offset estimation apparatus as described above, a variable vector representing the geomagnetism in the rectangular coordinate system when the equipment is at the reference attitude may be defined as a reference variable vector, the reference variable vector minimizing the objective function may be defined as a reference estimated geomagnetic vector, and a vector obtained by changing the reference estimated geomagnetic vector by the attitude variation may be defined as an estimated geomagnetic vector, and the offset estimation apparatus may include a first matrix calculation unit for calculating an estimated geomagnetic data distribution matrix representing distribution of a predetermined number of the estimated geomagnetic vectors respectively corresponding to a predetermined number of attitude variations calculated by the attitude calculation unit, a second matrix calculation unit for calculating an magnetic data distribution matrix representing distribution of a predetermined number of magnetic data output from the three-dimensional magnetic sensor, a similarity determination unit for determining whether or not eigenvalues and eigenvectors of the estimated geomagnetic data distribution matrix and eigenvalues and eigenvectors of the magnetic data distribution matrix satisfy some or all selected from among a first condition indicating that an eigenvector corresponding to a maximum eigenvalue of the estimated geomagnetic data distribution matrix and an eigenvector corresponding to a maximum eigenvalue of the magnetic data distribution matrix are parallel to each other or an angle between the two eigenvectors is equal to or less than a predetermined angle, a second condition indicating that an eigenvector corresponding to a middle eigenvalue of the estimated geomagnetic data distribution matrix and an eigenvector corresponding to a middle eigenvalue of the magnetic data distribution matrix are parallel to each other or an angle between the two eigenvectors is equal to or less than a predetermined angle, a third condition indicating that an eigenvector corresponding to a minimum eigenvalue of the estimated geomagnetic data distribution matrix and an eigenvector corresponding to a minimum eigenvalue of the magnetic data distribution matrix are parallel to each other or an angle between the two eigenvectors is equal to or less than a predetermined angle, a fourth condition indicating that an index value representing a degree of approximation between the maximum eigenvalue of the estimated geomagnetic data distribution matrix and the maximum eigenvalue of the magnetic data distribution matrix is equal to or greater than a predetermined value, a fifth condition indicating that an index value representing a degree of approximation between the middle eigenvalue of the estimated geomagnetic data distribution matrix and the middle eigenvalue of the magnetic data distribution matrix is equal to or greater than a predetermined value, and a sixth condition indicating that an index value representing a degree of approximation between the minimum eigenvalue of the estimated geomagnetic data distribution matrix and the minimum eigenvalue of the magnetic data distribution matrix is equal to or greater than a predetermined value, and an offset adoption unit for adopting the estimation value of the offset as the offset in a case in which a determination result of the similarity determination unit is positive.

### 4. ACCURACY DETERMINATION PROCESS

Next, the accuracy determination process will be described.

As previously described, the accuracy determination process performed by the accuracy determination unit 130 is a process of determining whether or not, in a case in which the offset calculation unit 140 calculates an estimation value c_{E} of the offset c_{OFF} based on the attitude rotation matrices R₁ to R_{N} stored in the memory unit 300, accuracy of the calculation is high. In other words, the accuracy determination process is a process of determining whether or not the attitude rotation matrices R₁ to R_{N} stored in the memory unit 300 are data suitable for calculating the estimation value c_{E} of the offset c_{OFF}.

As previously described, the offset calculation unit 140 solves a simultaneous linear equation represented by Equation (18) to obtain an optimal solution X_{OPT} and calculates an estimation value c_{E} based on the optimal solution x_{OPT}.

Generally, in a case in which, for calculation to obtain a solution of a simultaneous linear equation, a minimum eigenvalue of a coefficient matrix of the simultaneous linear equation is a small value, accuracy of the calculation is lower than in a case in which the minimum eigenvalue of the coefficient matrix of the simultaneous linear equation is a large value. Consequently, it is possible to evaluate accuracy of the calculation based on the minimum eigenvalue of the coefficient matrix of the simultaneous linear equation.

In the accuracy determination process according to this embodiment, a minimum eigenvalue λ_{Q, MIN} of a coefficient matrix of the simultaneous linear equation represented by Equation (18), i.e. a positive definite symmetric matrix Q, is defined as an accuracy index representing accuracy of calculation to obtain the solution of the simultaneous linear equation. The accuracy determination unit 130 determines whether or not accuracy of calculation represented by Equation (18) is equal to or greater than a predetermined accuracy based on the accuracy index, i.e. the minimum eigenvalue λ_{Q, MIN}.

Hereinafter, the accuracy determination process performed by the accuracy determination unit 130 will be described in detail.

As shown in FIG. 5, the accuracy determination process includes an index generation unit 132 and a condition determination unit 134.

The index generation unit 132 generates a minimum eigenvalue λ_{Q, MIN} (i.e. accuracy index) of the matrix Q based on the attitude rotation matrices R₁ to R_{N} stored in the memory unit 300.

The condition determination unit 134 determines whether or not the eigenvalue λ_{Q, MIN} generated by the index generation unit 132 satisfies a condition represented by Equation (32) below to determine whether or not accuracy of calculation to obtain the solution of the simultaneous linear equation represented by Equation (18) is equal to or greater than a predetermined accuracy. Here, a threshold value β present in Equation (32) is a predetermined positive real number.

λ_{Q,MIN}≧β Equation (32)

In a case in which the determination result of the condition determination unit 134 is positive, i.e. the eigenvalue λ_{Q, MIN} satisfies the condition represented by Equation (32), accuracy of calculation to obtain the solution of the simultaneous linear equation represented by Equation (32) can be regarded as being equal to or greater than a predetermined accuracy. Consequently, the estimation value c_{E} (optimal solution x_{OPT}) calculated by Equation (18) can be regarded as a value correctly representing the offset c_{OFF}. In this case, therefore, the offset calculation unit 140 calculates the estimation value c_{E} of the offset c_{OFF} based on the attitude rotation matrices R₁ to R_{N} stored in the memory unit 300.

On the other hand, in a case in which the determination result of the condition determination unit 134 is negative, there is a high possibility that the estimation value c_{E} may not correctly represent the offset c_{OFF}. In this case, therefore, the offset calculation unit 140 does not calculate the estimation value c_{E} of the offset c_{OFF}.

In this way, the accuracy determination unit 130 determines whether or not calculation of the estimation value c_{E} of the offset c_{OFF} performed by the offset calculation unit 140 based on the attitude rotation matrices R₁ to R_{N} stored in the memory unit 300 is proper by determining whether or not the eigenvalue λ_{Q, MIN} satisfies the condition represented by Equation (32).

As described above, the offset estimation apparatus may include an index generation unit for generating an accuracy index representing accuracy of calculation for the offset calculation unit to calculate the estimation value of the offset and a second determination unit for determining whether or not the accuracy index is equal to or greater than a predetermined threshold value, which is a positive real number, the objective function may be a function having, as a variable, a variable vector including each element of a reference variable vector, which is a variable representing the geomagnetism in the rectangular coordinate system when the attitude of the equipment is the reference attitude and each element of the offset variable vector as elements, the accuracy index may be a minimum eigenvalue of a coefficient matrix in a case in which the objective function is expressed in a quadratic form having each element of the variable vector as a variable, and the offset calculation unit may calculate the estimation value of the offset in a case in which a determination result of the second determination unit is positive and may not calculate the estimation value of the offset in a case in which the determination result of the second determination unit is negative.

The offset estimation apparatus according to the present invention can pre-evaluate accuracy of calculation performed by the offset calculation unit based on the accuracy index. In a case in which it is expected that accuracy of calculation performed by the offset calculation unit is low, therefore, it is possible to prevent the calculation from being performed. Consequently, it is possible for the offset estimation apparatus according to the present invention to prevent an incorrect estimate of the offset greatly deviating from a real offset from being calculated.

### 5. CONCLUSION

As described above, the offset estimation apparatus 100 according to this embodiment includes the offset calculation unit 140 for calculating the estimation value c_{E} of the offset c_{OFF} based on the attitude rotation matrices R₁ to R_{N} and the magnetic vectors m₁ to m_{N} stored in the memory unit 300.

The estimation value of the offset c_{OFF} may also be calculated based only on the result of output from the three-dimensional magnetic sensor as disclosed, for example, in Japanese Patent Application Publication No. 2012-198112.

However, it is possible to calculate the estimation value of the offset c_{OFF} more accurately or within a shorter time when the estimation value of the offset c_{OFF} is calculated based on a combination of the results of output from a plurality of sensors for detecting different kinds of physical quantities than when the estimation value of the offset c_{OFF} is calculated based on the result of output from one sensor for detecting one kind of physical quantity. In addition, it is possible to accurately calculate the estimation value of the offset c_{OFF} even under a worse condition.

Here, such worse condition includes a case in which the change in attitude of the portable equipment 1 is small, for example, in a case in which all of the attitude A₁ to A_{N} are almost the same as the attitude A₁ and each of the attitude rotation matrices R₁ to R_{N} and the unit matrix I_{3×3} are regarded as the same matrix or N rotation axes in N attitude changes represented by the attitude rotation matrices R₁ to R_{N} are regarded as the same axis.

The change in attitude of the portable equipment 1 can be expressed as distribution of a plurality of points on the sensor coordinate system Σ_{S} indicated by the magnetic vectors m₁ to m_{N}. And the estimation value of the offset c_{OFF} is calculated using a statistical method based on the distribution shape of the points. In a case in which the estimation value of the offset c_{OFF} is calculated based only on the magnetic vectors m₁ to m_{N}, therefore, the magnetic vectors m₁ to m_{N} are not widely distributed in the sensor coordinate system Σ_{S} under a bad condition that the change in attitude of the portable equipment 1 is small. As a result, the change in attitude of the portable equipment 1 is buried in noise of the magnetic vectors m₁ to m_{N} even in a case in which the distribution of the magnetic vectors m₁ to m_{N} is caused by the change in attitude of the portable equipment 1. For this reason, the change in attitude of the portable equipment 1 is not correctly reflected with respect to the calculated estimation value of the offset c_{OFF}. That is, in this case, it is not possible to correctly obtain the estimation value of the offset c_{OFF}.

In this embodiment, on the other hand, the estimation value c_{E} of the offset c_{OFF} is calculated based on the attitude rotation matrices R₁ to R_{N} generated using the angular velocity vectors ω₁ to ω_{N} represented by the angular velocity data W₁ to W_{N} output from the three-dimensional angular velocity sensor 60 in addition to the magnetic vectors m₁ to m_{N} represented by the magnetic data M₁ to M_{N} output from the three-dimensional magnetic sensor 50. Since the angular velocity vectors ω₁ to ω_{N} directly represent the change in attitude of the portable equipment 1, it is possible for the angular velocity vectors ω₁ to ω_{N} to correctly represent the change in attitude of the portable equipment 1 even in a case in which the change in attitude of the portable equipment 1 is small. Even under the poor condition that the change in attitude of the portable equipment 1 is small, therefore, it is possible to prevent the change in attitude of the portable equipment 1 from being regarded as noise and to use the change in attitude of the portable equipment 1 in calculating the estimation value c_{E} of the offset c_{OFF}. Consequently, it is possible for the offset estimation apparatus 100 according to this embodiment to calculate the estimation value c_{E} of the offset c_{OFF}, with respect to which the change in attitude of the portable equipment 1 is more correctly and sensitively reflected than in a case in which the estimation value of the offset c_{OFF} is calculated based only on the magnetic vectors m₁ to m_{N}.

In this way, it is possible for the offset estimation apparatus 100 according to this embodiment to more accurately calculate the estimation value c_{E} of the offset c_{OFF} even under the worse condition than in a case in which the estimation value of the offset c_{OFF} is calculated based only on the result of output from the three-dimensional magnetic sensor.

In addition, the offset estimation apparatus 100 according to this embodiment includes the distribution shape determination unit 150 for performing the process of determining whether or not the magnetic vectors mᵢ to m_{N} stored in the memory unit 300 are data suitable for calculating the estimation value c_{E} of the offset c_{OFF}, i.e. the distribution determination process.

In a case in which the magnetic vectors m₁ to m_{N} stored in the memory unit 300 are data not suitable for calculating the estimation value c_{E} of the offset c_{OFF} due to influence of noise, therefore, it is possible to determine that the estimation value c_{E} of the offset c_{OFF} calculated by the offset calculation unit 140 is a value not correctly representing the offset c_{OFF}.

Meanwhile, determination as to whether or not the magnetic vectors m₁ to m_{N} stored in the memory unit 300 are data suitable for calculating the estimation value c_{E} of the offset c_{OFF}, i.e. determination as to whether or not the distribution shape of a plurality of points on the sensor coordinate system Σ_{S} indicated by the magnetic vectors m₁ to m_{N} can be regarded as a spherical surface, may be performed based only on the result of output from the three-dimensional magnetic sensor as disclosed, for example, in Japanese Patent Application Publication No. 2012-198112.

However, it is possible to perform the determination more accurately or within a shorter time when the determination is performed based on a combination of the results of output from a plurality of sensors for detecting different kinds of physical quantities than when the determination is performed based on the result of output from one sensor for detecting one kind of physical quantity.

The distribution shape determination unit 150 according to this embodiment performs the distribution determination process based on the attitude rotation matrices R₁ to R_{N} set using the angular velocity vectors ω₁ to ω_{N} represented by the angular velocity data W₁ to W_{N} output from the three-dimensional angular velocity sensor 60 in addition to the magnetic vectors m₁ to m_{N} represented by the magnetic data M₁ to M_{N} output from the three-dimensional magnetic sensor 50. Consequently, it is possible for the offset estimation apparatus 100 according to this embodiment to perform the distribution determination process within a shorter time and more accurately than in a case in which the distribution determination process is performed based only on the result of output from the three-dimensional magnetic sensor.

In addition, the offset estimation apparatus 100 according to this embodiment includes the accuracy determination unit 130 for performing the process of determining whether or not, in a case in which the estimation value c_{E} of the offset c_{OFF} is calculated based on the attitude rotation matrices R₁ to R_{N} stored in the memory unit 300, accuracy of the calculation is high, i.e. the accuracy determination process.

In a case in which it is assumed that accuracy of the calculation to calculate the estimation value c_{E} based on the attitude rotation matrices R₁ to R_{N} stored in the memory unit 300 is low, therefore, it is possible to prevent the offset calculation unit 140 from performing the offset calculation process, i.e. the process of calculating the estimation value c_{E}. As a result, it is possible to prevent the estimation value c_{E} not correctly representing the offset c_{OFF} from being calculated.

### B. Second Embodiment

In the first embodiment as described above, the distribution shape determination unit 150 performs the distribution determination process using the reference estimated geomagnetic vector r_{E1} calculated by the offset calculation unit 140.

A second embodiment is different from the first embodiment in that the distribution determination process is performed based only on the attitude rotation matrices R₁ to R_{N} and the magnetic vectors m₁ to m_{N} stored in the memory unit 300 without using the output value from the offset calculation unit.

Meanwhile, elements of each embodiment, which will hereinafter be illustrated, identical in operation and function to those of the first embodiment will be denoted by the symbols used in the above description and a detailed description thereof will be omitted (The same is equally applied to embodiments and modifications which will hereinafter be described).

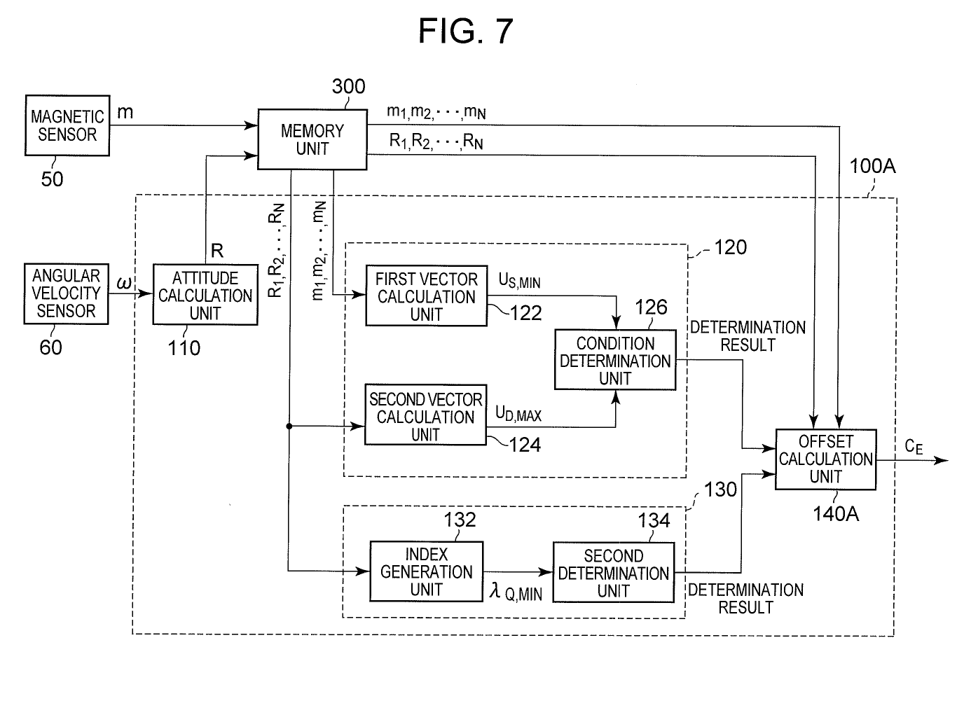

FIG. 7 is a block diagram showing a function of an offset estimation apparatus 100A according to a second embodiment.

The offset estimation apparatus 100A is identical in configuration to the offset estimation apparatus 100 according to the first embodiment except that the offset estimation apparatus 100A includes a distribution shape determination unit 120 instead of the distribution shape determination unit 150 and an offset calculation unit 140A instead of the offset calculation unit 140 and does not include the adoption unit 160.

In a case in which the result of the determination performed by the distribution shape determination unit 120 is positive and the result of the determination performed by the accuracy determination unit 130 is positive, the offset calculation unit 140 calculates an estimation value c_{E} of the offset c_{OFF}. Meanwhile, an offset calculation process performed by the offset calculation unit 140A is identical to the offset calculation process performed by the offset calculation unit 140 according to the first embodiment.

The distribution shape determination unit 120 performs a distribution determination process based on the attitude rotation matrices R₁ to R_{N} and the magnetic vectors m₁ to m_{N} stored in the memory unit 300.

As shown in FIG. 7, the distribution shape determination unit 120 includes a first vector calculation unit 122, a second vector calculation unit 124, and a condition determination unit 126.

The first vector calculation unit 122 calculates a normalized eigenvector u_{S, MIN} corresponding to the minimum eigenvalue λ_{S MIN} of the matrix S represented by Equation (20) based on the magnetic vectors m₁ to m_{N} stored in the memory unit 300.

The second vector calculation unit 124 calculates a normalized eigenvector u_{D, MAX} corresponding to a maximum eigenvalue λ_{D, MAX} of a matrix D represented by Equation (33) below based on the attitude rotation matrices R₁ to R_{N} stored in the memory unit 300. Meanwhile, the second vector calculation unit 124 may calculate the eigenvector u_{D, MAX} by calculating the matrix D using the matrix R_{AVE} calculated by the offset calculation unit 140.

D=R_{AVE}^{T}R_{AVE} Equation (33)

The condition determination unit 126 determines whether or not the eigenvector u_{S, MIN} calculated by the first vector calculation unit 122 and the eigenvector u_{D, MAX} calculated by the second vector calculation unit 124 can be regarded as being parallel to each other.

Specifically, the condition determination unit 126 determines whether or not the eigenvector u_{S, MIN} and the eigenvector u_{D, MAX} can be regarded as being parallel to each other by determining whether or not the eigenvector u_{S, MIN} and the eigenvector u_{D, MAX} satisfy a condition represented by Equation (34) below. Here, a value γ present in Equation (34) is a predetermined real number satisfying 0<γ<1.

In a case in which the result of the determination performed by the condition determination unit 126 is positive, i.e. in a case in which the eigenvector u_{S, MIN} and the eigenvector u_{D, MAX} are regarded as being parallel to each other, the estimation value c_{E} calculated based on the magnetic vectors m₁ to m_{N} stored in the memory unit 300 can be regarded as correctly representing the offset c_{OFF}. On the other hand, in a case in which the result of the determination performed by the condition determination unit 126 is negative, there is a high possibility that the estimation value c_{E} calculated based on the magnetic vectors m₁ to m_{N} stored in the memory unit 300 may not correctly represent the offset c_{OFF}.

In this way, the distribution shape determination unit 120 determines whether or not calculation of the estimation value c_{E} of the offset c_{OFF} performed by the offset calculation unit 140 based on the magnetic vectors m₁ to m_{N} stored in the memory unit 300 is proper by determining whether or not the eigenvector u_{S, MIN} and the eigenvector u_{D, MAX} satisfy the condition represented by Equation (34).

|u_{D,MAX}·u_{S,MIN}|≧γ Equation (34)

### C. Modifications

The present invention is not limited to the above embodiments but may be modified as follows. In addition, two or more of the following modifications may be properly combined within the scope of non-contradiction.

### (1) First Modification

Although, in the first embodiment as described above, the distribution shape determination unit 150 performs the distribution determination process by performing the first determination, the distribution determination process is not restricted so long as the distribution shape determination unit 150 can determine whether or not the distribution shape of a plurality of points on the sensor coordinate system Σ_{S} indicated by the magnetic vectors m₁ to m_{N} can be regarded as a spherical surface.

For example, the distribution determination process may be performed using a method disclosed in Japanese Patent Application Publication No. 2012-198112.

### (2) Second Modification

Although, in the embodiments and the modification as described above, the offset estimation apparatus 100 includes the attitude calculation unit 110, the accuracy determination unit 130, the offset calculation unit 140, the distribution shape determination unit 150, and the adoption unit 160, the offset estimation apparatus 100 may at least include the attitude calculation unit 110 and the offset calculation unit 140.

### (3) Third Modification

Although, in the embodiments and the modifications as described above, the offset estimation program 200 is stored in the ROM 30, the offset estimation program 200 may be recorded in a recording medium readable by the portable equipment 1 or a memory device included in a server device that is capable of communicating with the portable equipment 1.

In addition, the present invention provides a program of an offset estimation apparatus provided at equipment including a three-dimensional angular velocity sensor for periodically detecting angular velocities in three directions and for sequentially outputting detection results as angular velocity data and a three-dimensional magnetic sensor for periodically detecting magnetic components in three directions including geomagnetism and for sequentially outputting detection results as magnetic data, which are vector data in a three-axis rectangular coordinate system, to estimate an estimation value of an offset of the three-dimensional magnetic sensor using a computer, wherein the computer is functioned as an attitude calculation unit for periodically calculating an attitude variation of the equipment from a reference attitude based on the angular velocity data, a variable vector representing the geomagnetism in the rectangular coordinate system when the attitude of the equipment is changed from the reference attitude by the attitude variation being defined as a first variable vector, a variable vector obtained by subtracting an offset variable vector, which is a variable vector representing the estimation value of the offset, from the magnetic data being defined as a second variable vector, and an offset calculation unit for calculating the offset variable vector minimizing an objective function representing an error between a predetermined number of the first variable vectors corresponding to a predetermined number of attitude variations generated by the attitude calculation unit and a predetermined number of the second variable vectors corresponding to a predetermined number of magnetic data output from the three-dimensional magnetic sensor as the estimation value of the offset.

What is claimed is:

1. A method of estimating an offset of a magnetic sensor that is provided in equipment for detecting magnetism including geomagnetism, the equipment having an angular velocity sensor for detecting an angular velocity of the equipment, the method comprising:
calculating attitude data representing an attitude variation of the equipment from a reference attitude thereof based on angular velocity data that is outputted from the angular velocity sensor and that represents the detected angular velocity of the equipment; and
calculating an estimation value of the offset minimizing an error between a predetermined number of first variable vectors associated to a predetermined number of the attitude data that are successively calculated in response to the angular velocity data outputted from the angular velocity sensor and a predetermined number of second variable vectors associated to a predetermined number of the magnetic data that are successively outputted from the magnetic sensor and that represent the detected magnetism including the geomagnetism, wherein
the first variable vector is obtained by changing a reference variable vector in accordance with the attitude variation represented by the attitude data, the reference variable vector representing the geomagnetism when the equipment is placed in the reference attitude, and
the second variable vector is obtained by subtracting the estimation value of the offset from the magnetic data.

2. The method according to claim 1, wherein the estimation value of the offset is calculated as an offset variable vector that minimizes an objective function representing the error between the predetermined number of the first variable vectors and the predetermined number of the second variable vectors.

3. The method according to claim 1, further comprising:
determining whether or not a degree of difference between a distribution shape of a predetermined number of points indicated by the predetermined number of the first variable vectors and a distribution shape of a predetermined number of points indicated by the predetermined number of the second variable vectors is within a predetermined range; and
adopting the estimation value of the offset as the offset of the magnetic sensor in case that the degree of the difference is determined to be within the predetermined range.

4. The method according to claim 1, further comprising:
determining whether or not a degree of difference between components of an estimated geomagnetic data distribution matrix representing distribution of the predetermined number of the first variable vectors and components of a magnetic data distribution matrix representing distribution of the predetermined number of the magnetic data is within a predetermined range; and
adopting the estimation value of the offset as the offset of the magnetic sensor in case that the degree of the difference is determined to be within the predetermined range.

5. The method according to claim 1, further comprising:
generating an accuracy index representing accuracy of calculation for calculating the estimation value of the offset; and
determining whether or not the accuracy index is equal to or greater than a predetermined threshold value, wherein
the estimation value of the offset is calculated in case that the accuracy index is determined to be equal to or greater than the predetermined threshold value, and the estimation value of the offset is not calculated in case that the accuracy index is determined to be less than the predetermined threshold value.

6. The method according to claim 5, wherein the error is represented by a function using variables including elements of the reference variable vector and elements of an offset variable vector representing the estimation value of the offset, and the accuracy index is a minimum eigenvalue of a coefficient matrix that is given by expressing the error in a quadratic form based on the variables.

7. The method according to claim 6, wherein the predetermined threshold value is a positive real number.

8. An apparatus for estimating an offset of a magnetic sensor that is provided in equipment for detecting magnetism including geomagnetism, the equipment having an angular velocity sensor for detecting an angular velocity of the equipment, the apparatus comprising one or more processors configured to:
calculate attitude data representing an attitude variation of the equipment from a reference attitude thereof based on angular velocity data that is outputted from the angular velocity sensor and that represents the detected angular velocity of the equipment; and
calculate an estimation value of the offset minimizing an error between a predetermined number of first variable vectors associated to a predetermined number of the attitude data that are successively calculated in response to the angular velocity data outputted from the angular velocity sensor and a predetermined number of second variable vectors associated to a predetermined number of the magnetic data that are successively outputted from the magnetic sensor and that represent the detected magnetism including the geomagnetism, wherein
the first variable vector is obtained by changing a reference variable vector in accordance with the attitude variation represented by the attitude data, the reference variable vector representing the geomagnetism when the equipment is placed in the reference attitude, and
the second variable vector is obtained by subtracting the estimation value of the offset from the magnetic data.

9. The apparatus according to claim 8, wherein the estimation value of the offset is calculated as an offset variable vector that minimizes an objective function representing the error between the predetermined number of the first variable vectors and the predetermined number of the second variable vectors.

10. The apparatus according to claim 8, wherein the one or more processors are further configured to:
determine whether or not a degree of difference between a distribution shape of a predetermined number of points indicated by the predetermined number of the first variable vectors and a distribution shape of a predetermined number of points indicated by the predetermined number of the second variable vectors is within a predetermined range; and
adopt the estimation value of the offset as the offset of the magnetic sensor in case that the degree of the difference is determined to be within the predetermined range.

11. The apparatus according to claim 8, wherein the one or more processors are further configured to:
determine whether or not a degree of difference between components of an estimated geomagnetic data distribution matrix representing distribution of the predetermined number of the first variable vectors and components of a magnetic data distribution matrix representing distribution of the predetermined number of the magnetic data is within a predetermined range; and
adopt the estimation value of the offset as the offset of the magnetic sensor in case that the degree of the difference is determined to be within the predetermined range.

12. The apparatus according to claim 8, wherein the one or more processors are further configured to:
generate an accuracy index representing accuracy of calculation for calculating the estimation value of the offset; and
determine whether or not the accuracy index is equal to or greater than a predetermined threshold value, wherein
the estimation value of the offset is calculated in case that the accuracy index is determined to be equal to or greater than the predetermined threshold value, and the estimation value of the offset is not calculated in case that the accuracy index is determined to be less than the predetermined threshold value.

13. The apparatus according to claim 12, wherein the error is represented by a function using variables including elements of the reference variable vector and elements of an offset variable vector representing the estimation value of the offset, and the accuracy index is a minimum eigenvalue of a coefficient matrix that is given by expressing the error in a quadratic form based on the variables.

14. The apparatus according to claim 13, wherein the predetermined threshold value is a positive real number.
